(19) United States
(12) Patent Application Publication
(10) Pub. No.: US 2026/0186400 A1
(43) Pub. Date: Jul. 2, 2026

(54) IMPROVED RETICLE AND RETICLE BLANK

(71) Applicant: ASML Netherlands B.V., Veldhoven (NL)

(72) Inventors: Marinus JOCHEMSEN, Veldhoven (NL); Justin RADEMAKER, Tull en ‘t Waal (NL); Emilio BAJONERO CANONICO, Eindhoven (NL)

(73) Assignee: ASML Netherlands B.V., Veldhoven (NL)

(21) Appl. No.: 19/130,332

(22) PCT Filed: Nov. 1, 2023
(86) PCT No.: PCT/EP2023/080467

§ 371 Date: May 15, 2025

(30) Foreign Application Priority Data
Dec. 7, 2022 (EP) 22211871.3

(51) Int. Cl. G03F 1/22; G03F 7/00; G06F 30/20

(52) U.S. Cl. CPC G03F 1/22; G03F 7/70733; G06F 30/20

(57) ABSTRACT

There is provided a reticle or a reticle blank comprising a low deformation material, wherein the reticle or reticle blank material has a Zero Crossing Temperature (ZCT) profile, and a ZCT slope profile, wherein at least one of the ZCT profile and the ZCT slope profile is non-uniform. Also provided is a method of mitigating non-correctable deformations in a reticle or reticle blank, the method including providing a reticle or reticle blank having at least one of a Zero Crossing Temperature (ZCT) profile and a ZCT slope profile which is non-uniform across the reticle or reticle blank.

### CROSS-REFERENCE TO RELATED APPLICATIONS

This application claims priority of EP application 22211871.3 which was filed on 7 Dec. 2022, and which is incorporated herein in its entirety by reference.

### FIELD

The present disclosure relates a reticle or a reticle blank, particularly with a non-uniform zero crossing temperature and/or zero crossing temperature slope. The present disclosure also relates to a reticle clamp and a lithographic apparatus including such a reticle. The present disclosure also includes a method of mitigating non-correctable deformations in a reticle or reticle blank, as well as a method of producing a reticle or reticle blank. The present disclosure has particular, but no exclusive, application to reticles and reticle blanks for lithography, particularly EUV lithography.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g. a mask) onto a layer of radiation-sensitive material (resist) provided on a substrate.

The wavelength of radiation used by a lithographic apparatus to project a pattern onto a substrate determines the minimum size of features which can be formed on that substrate. A lithographic apparatus which uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A lithographic apparatus includes a patterning device (e.g. a mask or reticle). Radiation is provided through or reflected off the patterning device to form an image on a substrate. A membrane assembly, also referred to as a pellicle, may be provided to protect the patterning device from airborne particles and other forms of contamination. Contamination on the surface of the patterning device can cause manufacturing defects on the substrate.

In use, the reticle is exposed to a beam of radiation, which causes the reticle to heat up. In order to manage the temperature of the reticle, the reticle is provided with cooling, which may be in the form of liquid cooling. The reticle is supported by a reticle clamp that holds the reticle in place. Even though the temperature of the reticle is controlled, the shape of the reticle changes upon exposure to the radiation beam, which causes deformation of the reticle that can lead to overlay issues. Whilst some deformation may be corrected by alignment adjustments, there remains parts of the deformation which cannot be corrected by existing methods, and are therefore non-correctable.

The present invention has been devised in an attempt to address at least some of the problems identified above.

### SUMMARY OF THE INVENTION

According to a first aspect of the present disclosure, there is provided a reticle or a reticle blank comprising a low deformation material, wherein the reticle or reticle blank material has a Zero Crossing Temperature (ZCT) profile, and a ZCT slope profile, wherein at least one of the ZCT profile and the ZCT slope profile is non-uniform.

Reticles and reticle blanks for use in lithographic apparatus and processes are generally made from ultra-low expansion (ULE) glass. ULE is used as its shape changes by only a small amount as compared to other materials when its temperature changes. In use, the ULE glass will absorb a large amount of energy from the radiation beam and heat it. Although cooling can be used to control the temperature of the reticle, there is necessarily some degree of heating. The reticles are supported by a reticle clamp, which means that the reticle deforms when constrained by the clamp. Whilst some of these deformations are correctable by aligning the reticle using fiducial marks on the reticle, higher-order deformations are non-correctable by existing means. The present disclosure addresses this shortcoming by providing a reticle or reticle blank for which one or both of the zero crossing temperature profile and the ZCT slope profile are non-uniform. The zero crossing temperature is the temperature at which or temperature range over which the material comprising the reticle crosses zero. In this way, the materials, such as ULE glass, have a temperature or temperature range where the coefficient of thermal expansion crosses zero. As such, around the zero crossing temperature, the material is dimensionally stable to temperature fluctuations. The zero crossing temperature slope is the rate at which the coefficient of thermal expansion changes around the zero crossing temperature. Existing reticles and reticle blanks are manufactured to have as uniform a ZCT profile as possible. The ZCT slope profile is based on the length of the annealing process of the material used to form the reticle or reticle blank. This leads to in-use deformations which are non-correctable. The present disclosure provides for a reticle or reticle blank which has a non-uniform ZCT profile and/or ZCT slope profile such that different parts of the reticle or reticle blank deform in different ways in use. This allows for the reticle or reticle blank to be configured to have different deformation characteristics in use and to limit the degree of non-correctable deformations.

The reticle or reticle blank may comprise ultra-low expansion glass.

It will be appreciated that the reticle or reticle blank has x, y, and z-directions. Preferably, at least one of the ZCT profile and ZCT slope profile vary in the y-direction. As such, the ZCT profile and/or ZCT slope profile in the y-direction can be configured such that it is a lower-order profile, such as a quadratic profile, which can be readily corrected. Without the variance in the ZCT profile, the deformations are higher-order, such as higher than quadratic, which cannot be corrected.

At least one of the ZCT profile and ZCT slope profile vary in a region adjacent to an edge of the reticle or reticle blank.

It has been found that varying the ZCT profile and/or ZCT slope profile adjacent to an edge of the reticle or reticle blank is advantageous to reduce the non-correctable deformations. Without wishing to be bound by scientific theory, it is believed that the deformations in the edge of the reticle or reticle blank are altered in situ when supported by the reticle clamp. By varying the ZCT profile and or ZCT slope profile as described, the deformations at the edge of the reticle or reticle blank can be controlled.

The ZCT of the reticle or reticle blank is higher at at least one border of the reticle or reticle blank.

By having the ZCT higher at the border of the reticle, it has been found that there can be an overlay improvement of over 35%.

The ZCT of the reticle or reticle blank has a range of around ±1° C., around ±2° C., around ±3° C., around ±4° C., around, ±5° C., around ±6° C., around ±7° C., around ±8° C., around ±9° C., or around ±10°C.

By having a ZCT with a larger range, the reticle or reticle blank is dimensionally stable over a greater range of temperatures.

The ZCT slope may be from around 0.5 ppb/K² to around 2.5 ppb/K². The ZCT may be from around 1.0 ppb/K² to around 2.0 ppb/K².

The ZCT profile and/or the ZCT slope profile has at least one axis of symmetry. The axis of symmetry may be the y-axis, x-axis, and/or z-axis.

According to a second aspect of the present disclosure, there is provided a reticle clamp including a reticle according to the first aspect.

According to a third aspect of the present disclosure, there is provided a lithographic apparatus including a reticle or reticle clamp according to the first or second aspects of the present disclosure.

The lithographic may be an EUV lithographic apparatus.

According to a fourth aspect of the present disclosure, there is provided a method of mitigating non-correctable deformations in a reticle or reticle blank, the method including providing a reticle or reticle blank having at least one of a Zero Crossing Temperature (ZCT) profile and a ZCT slope profile which is non-uniform across the reticle or reticle blank.

As described in relation to the first aspect of the present disclosure, providing a non-uniform ZCT profile and/or ZCT slope profile, it is possible to reduce the amount of non-correctable deformations in a reticle or reticle blank. This can then reduce overlay errors.

The method may include varying at least one of the ZCT profile and ZCT slope profile in a region adjacent to an edge of the reticle or reticle blank.

According to a fifth aspect of the present disclosure, there is provided a method of producing a reticle or reticle blank for a lithography process, the method including:
i) modelling deformation of the reticle or reticle blank under use conditions,
ii) based on the deformation modelling, calculating a Zero Crossing Temperature (ZCT) profile, and/or a ZCT slope profile of the reticle or reticle blank to decrease any modelled non-correctable deformations,
iii) optionally repeat steps i) and ii) until the modelled non-correctable deformations have been reduced to a predetermined level; and
iv) outputting an optimized Zero Crossing Temperature (ZCT) profile and/or a ZCT slope profile of the reticle or reticle blank; and
v) producing a reticle or reticle blank having the optimized Zero Crossing Temperature (ZCT) profile and/or a ZCT slope profile.

As described in relation to the other aspects of the present disclosure, it is possible to reduce the non-correctable deformations in a reticle or reticle blank by adjusting the ZCT profile and/or ZCT slope profile across the reticle or reticle blank. In other words, the ZCT and ZCT slope are different in different parts of the reticle or reticle blank. By modelling the deformation of the reticle or reticle blank, it is possible to reduce the non-correctable deformations by adjusting the ZCT profile and/or ZCT slope profile, and subsequently produce a reticle or reticle blank with the desired ZCT profile and/or ZCT slope profile.

According to a sixth aspect of the present disclosure, there is provided the use of a reticle or reticle blank according to the first aspect, a reticle clamp according to the second aspect, a lithograhic apparatus according to the third aspect, a method according to the fourth aspect, or a method according to the fifth aspect

It will be appreciated that features described in respect of one embodiment may be combined with any features described in respect of another embodiment and all such combinations are expressly considered and disclosed herein.

### BRIEF DESCRIPTION OF THE DRAWINGS

Embodiments of the invention will now be described, by way of example only, with reference to the accompanying schematic drawing in which corresponding reference symbols indicate corresponding parts, and in which:

FIG. 1 depicts a lithographic apparatus according to an embodiment of the disclosure;

FIG. 2 depicts the deformation of a reticle in a reticle clamp;

FIGS. 3a and 3b depict the deformation of a reticle with nominal uniform ZCT and the deformation of a reticle with a quadratic ZCT profile in the y-direction; and

FIG. 4 depicts one exemplary embodiment of a reticle or reticle blank in accordance with the present disclosure.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

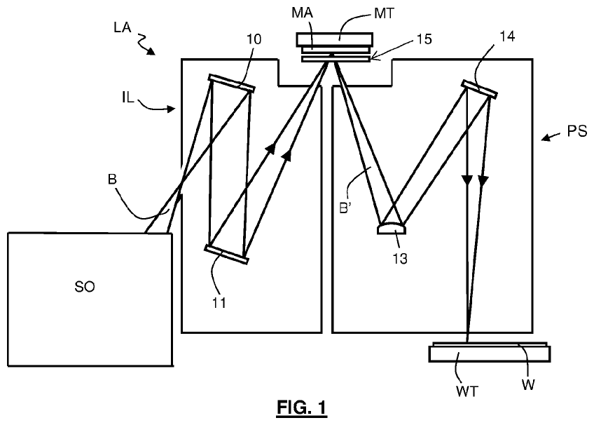

FIG. 1 shows a lithographic system according to the present invention. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a patterning device MA (e.g. a mask), a projection system PS and a substrate table WT configured to support a substrate W. The illumination system IL is configured to condition the radiation beam B before it is incident upon the patterning device MA. The projection system is configured to project the radiation beam B (now patterned by the mask MA) onto the substrate W. The substrate W may include previously formed patterns. Where this is the case, the lithographic apparatus aligns the patterned radiation beam B with a pattern previously formed on the substrate W. In this embodiment, a pellicle 15 is depicted in the path of the radiation and protecting the patterning device MA. It will be appreciated that the pellicle 15 may be located in any required position and may be used to protect any of the mirrors in the lithographic apparatus. The patterning device MA may be referred to as the reticle. The support structure MT may be referred to as the reticle stage.

The radiation source SO, illumination system IL, and projection system PS may all be constructed and arranged such that they can be isolated from the external environment. A gas at a pressure below atmospheric pressure (e.g. hydrogen) may be provided in the radiation source SO. A vacuum may be provided in illumination system IL and/or the projection system PS. A small amount of gas (e.g. hydrogen) at a pressure well below atmospheric pressure may be provided in the illumination system IL and/or the projection system PS.

The radiation source SO shown in FIG. 1 is of a type which may be referred to as a laser produced plasma (LPP) source. A laser, which may for example be a CO₂ laser, is arranged to deposit energy via a laser beam into a fuel, such as tin (Sn) which is provided from a fuel emitter. Although tin is referred to in the following description, any suitable fuel may be used. The fuel may for example be in liquid form, and may for example be a metal or alloy. The fuel emitter may comprise a nozzle configured to direct tin, e.g. in the form of droplets, along a trajectory towards a plasma formation region. The laser beam is incident upon the tin at the plasma formation region. The deposition of laser energy into the tin creates a plasma at the plasma formation region. Radiation, including EUV radiation, is emitted from the plasma during de-excitation and recombination of ions of the plasma.

The EUV radiation is collected and focused by a near normal incidence radiation collector (sometimes referred to more generally as a normal incidence radiation collector). The collector may have a multilayer structure which is arranged to reflect EUV radiation (e.g. EUV radiation having a desired wavelength such as 13.5 nm). The collector may have an elliptical configuration, having two ellipse focal points. A first focal point may be at the plasma formation region, and a second focal point may be at an intermediate focus, as discussed below.

The laser may be separated from the radiation source SO. Where this is the case, the laser beam may be passed from the laser to the radiation source SO with the aid of a beam delivery system (not shown) comprising, for example, suitable directing mirrors and/or a beam expander, and/or other optics. The laser and the radiation source SO may together be considered to be a radiation system.

Radiation that is reflected by the collector forms a radiation beam B. The radiation beam B is focused at a point to form an image of the plasma formation region, which acts as a virtual radiation source for the illumination system IL. The point at which the radiation beam B is focused may be referred to as the intermediate focus. The radiation source SO is arranged such that the intermediate focus is located at or near to an opening in an enclosing structure of the radiation source.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the patterning device MA held by the support structure MT. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 which are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system may include any number of mirrors (e.g. six mirrors).

The radiation sources SO shown in FIG. 1 may include components which are not illustrated. For example, a spectral filter may be provided in the radiation source. The spectral filter may be substantially transmissive for EUV radiation but substantially blocking for other wavelengths of radiation such as infrared radiation.

If the patterning device MA is left unprotected, the contamination can require the patterning device MA to be cleaned or discarded. Cleaning the patterning device MA interrupts valuable manufacturing time and discarding the patterning device MA is costly. Replacing the patterning device MA also interrupts valuable manufacturing time.

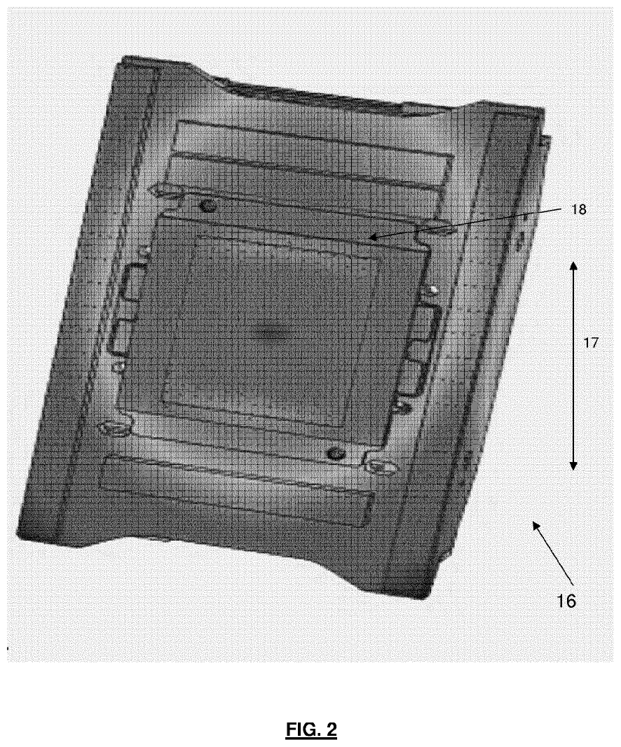

FIG. 2 depicts the deformation of a reticle MA in a reticle clamp 16. The shading relates to the degree of deformation of the reticle MA at operating temperature. As shown, the least amount of deformation of the reticle MA is in the centre of the reticle MA. At the edges of the reticle in the y-direction 17, the deformation is the greatest. In use, the reticle is loaded at around ambient temperature and when imaging of the reticle starts, the outer edge of the reticle expands as the area cools down to the operating temperature of the clamp 18 whereas the imaging area of the reticle expands as the radiation beam heats it up to a steady state temperature. The outer edge remains in the expanded cold state. The further away the reticle edge is from the zero crossing temperature, the bigger the strain in this area of the reticle. This can be seen in the depiction of FIG. 2 where the edges in the y-direction are shaded a different colour to the imaging area of the reticle MA. This differential strain causes non-correctable deformations.

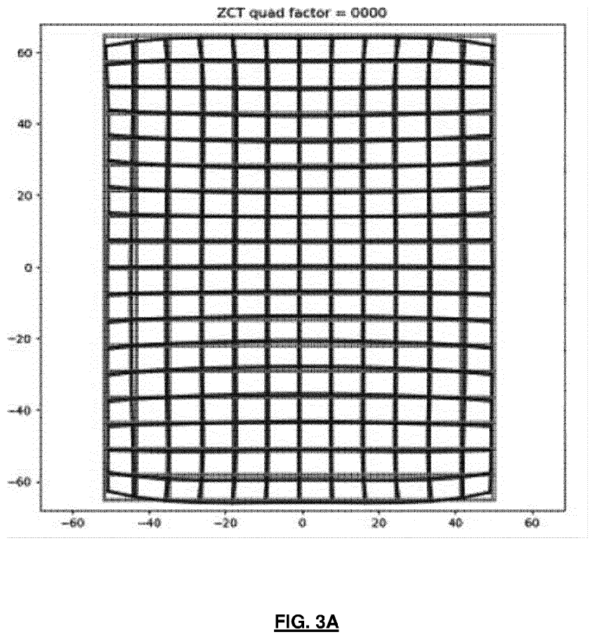

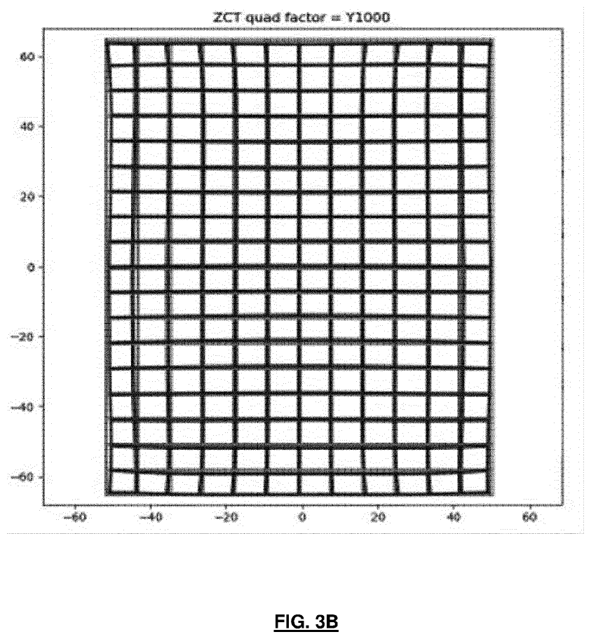

FIGS. 3a and 3b depict the deformation of a reticle with nominal uniform ZCT and the deformation of a reticle with a quadratic ZCT profile in the y-direction. In FIG. 3A, with a reticle having a uniform ZCT profile and/or ZT slope profile, at the y-borders, namely the top and bottom of the grid, there is a greater degree of deformation. Such deformation is not-correctable by normal alignment techniques. In such a case, the overlay can be optimised to around 0.5 nm. FIG. 3B depicts a reticle according to the present disclosure which is non-uniform. The deformations are decreased at the y-borders, which allows the overlay to be optimised to around 0.31 nm.

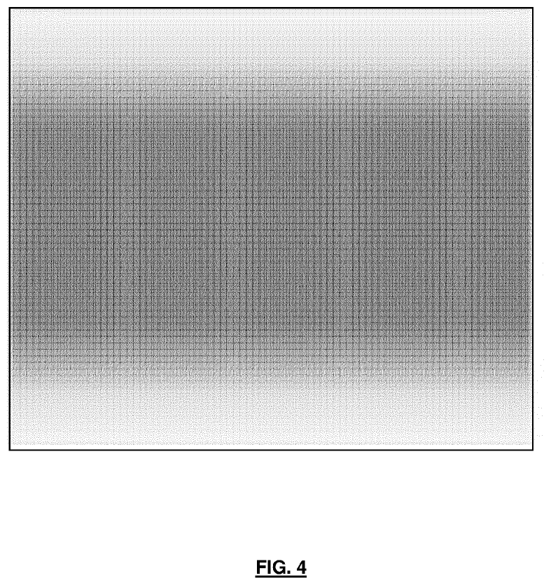

FIG. 4 depicts one exemplary embodiment of a reticle or reticle blank in accordance with the present disclosure. In this schematic figure, the ZCT of the reticle is depicted with the lowest ZCT being provided in the middle portion of the reticle and the ZCT increasing at the −Y and +Y reticle borders. In this embodiment, there is an axis of symmetry along both the y-axis and along the x-axis.

In summary, by providing a reticle or reticle blank with a non-uniform ZCT profile or ZCT slope profile, it is possible to reduce the amount of non-correctable deformations when in use. This improves the overlay accuracy of the apparatus in which it is used. Previously, reticles and reticle blanks were manufactured with the intention of providing a uniform ZCT profile and/or ZCT slope profile across the extent of the reticle or reticle blank.

While specific embodiments of the invention have been described above, it will be appreciated that the invention may be practiced otherwise than as described.

The descriptions above are intended to be illustrative, not limiting. Thus it will be apparent to one skilled in the art that modifications may be made to the invention as described without departing from the scope of the claims set out below.

1.-14. (canceled)

15. A reticle or a reticle blank, comprising:
a low deformation material having a Zero Crossing Temperature (ZCT) profile, and a ZCT slope profile, wherein at least one of the ZCT profile and the ZCT slope profile is non-uniform.

16. The reticle or reticle blank of claim 15, wherein the low deformation material comprises ultra-low expansion glass.

17. The reticle or reticle blank of claim 15, the reticle or reticle blank having x, y, and z-directions, and wherein at least one of the ZCT profile and ZCT slope profile vary in the y-direction.

18. The reticle or reticle blank of claim 15, wherein at least one of the ZCT profile and ZCT slope profile vary in a region adjacent to an edge of the reticle or reticle blank.

19. The reticle or reticle blank of claim 15, wherein the ZCT of the reticle or reticle blank is higher at least at one border of the reticle or reticle blank.

20. The reticle or reticle blank of claim 15, wherein the ZCT of the reticle or reticle blank has a range of around ±1° C., around ±2° C., around ±3° C., around ±4° C., around, ±5° C., around ±6° C., around ±7° C., around ±8° C., around ±9° C., or around ±10° C.

21. The reticle or reticle blank of claim 15, wherein the ZCT slope is from around 0.5 ppb/K² to around 2.5 ppb/K².

22. The reticle or reticle blank of claim 15, wherein the ZCT profile and/or the ZCT slope profile has at least one axis of symmetry.

23. A reticle clamp including a reticle of claim 15.

24. A lithographic apparatus including a reticle or reticle clamp of claim 15.

25. A method of mitigating non-correctable deformations in a reticle or reticle blank, comprising:
providing a reticle or reticle blank having at least one of a Zero Crossing Temperature (ZCT) profile and a ZCT slope profile that is non-uniform across the reticle or reticle blank.

26. The method of claim 25, wherein the method further comprises varying at least one of the ZCT profile and ZCT slope profile in a region adjacent to an edge of the reticle or reticle blank.

27. A method of producing a reticle or reticle blank for a lithography process, the method comprising:
modelling deformation of the reticle or reticle blank under use conditions;
based on the deformation modelling, calculating a Zero Crossing Temperature (ZCT) profile, and/or a ZCT slope profile of the reticle or reticle blank to decrease any modelled non-correctable deformations;
outputting an optimized Zero Crossing Temperature (ZCT) profile and/or a ZCT slope profile of the reticle or reticle blank; and
producing a reticle or reticle blank having the optimized Zero Crossing Temperature (ZCT) profile and/or a ZCT slope profile.

28. The method of claim 27, further comprising repeating the modelling and calculating until the modelled non-correctable deformations have been reduced to a predetermined level.
